(19) United States
(12) Patent Application Publication
(10) Pub. No.: US 2015/0103604 A1
(43) Pub. Date: Apr. 16, 2015

(54) MEMORY ARRAY ARCHITECTURES HAVING MEMORY CELLS WITH SHARED WRITE ASSIST CIRCUITRY

(71) Applicant: LSI Corporation, San Jose, CA (US)

(72) Inventors: Mohammed S.K. Sheikh, Bangalore (IN); Setti S. Rao, Bangalore (IN); Vinod Rachamadugu, Bangalore (IN)

(73) Assignee: LSI Corporation, San Jose, CA (US)

(21) Appl. No.: 14/102,649

(22) Filed: Dec. 11, 2013

(30) Foreign Application Priority Data
Oct. 14, 2013 (IN) 4627/CHE/2013

(51) Int. Cl. G11C 5/14; G11C 7/12

(52) U.S. Cl. CPC G11C 5/147; G11C 7/12
USPC 365/189.05; 365/226

(57) ABSTRACT

A memory device includes a memory array having a plurality of memory cells each having first and second power supply nodes, first and second virtual power supply nodes, a latch circuit, and a write assist circuit. The latch circuit includes a first and second inverters in a cross-coupled inverter configuration. The first inverter is connected between the first virtual power supply node and the second power supply node, and the second inverter is connected between the second virtual power supply node and the second power supply node. The write assist circuit selectively supplies power to the first and second virtual power supply nodes during memory access operations, and is controlled by a first control signal to switchably connect the first power supply node to and from the first and second virtual power supply nodes, and a second control signal to switchably connect the one or both of the first and second virtual power supply nodes to a virtual power supply node of an adjacent memory cell of an adjacent row in the memory array.

### CROSS-REFERENCE TO RELATED APPLICATION

This application claims foreign priority to India Patent Application No. 4627/CHE/2013, filed on 14 Oct. 2013, the disclosure of which is incorporated herein by reference.

### FIELD OF THE INVENTION

The field generally relates generally to semiconductor memory devices, and more particularly, to memory array architectures having write assist circuitry that is shared between memory cells.

### BACKGROUND

A semiconductor memory device typically includes an array of memory cells arranged in rows and columns, with each memory cell configured to store one or more bits of data. The memory cells within a given row of the array are coupled to a common wordline, and the memory cells within a given column of the array are coupled to a common bitline. As transistor dimensions continue to shrink, it is becoming increasingly difficult to prevent local mismatch between transistors of a memory cell, which can adversely affect performance of the memory device, such as the ability to consistently write data to the memory cells at low operating voltages. This issue arises in a conventional six-transistor (6T) static random access memory (SRAM) memory cells, for example, in which worst case local variations cause an increase in a threshold voltage of an NMOS pass gate transistor, and a decrease in a threshold voltage of a PMOS pull-up transistor of a cross-coupled inverter latch. Under these worse case local variations, with low operating voltages, an NMOS pass gate transistor coupled to a bitline may not be able to drive a corresponding inverter input of a memory cell below its trip point, thereby resulting in a write failure for the memory cell. Various techniques for improving bit cell write-ability have been proposed. For example, negative bootstrapping techniques use a boost signal to provide an additional negative voltage to a bitline during a write operation to thereby increase the drive of an NMOS pass gate drive and allow the inverter input to be driven below its trip point. Moreover, charge pump-based VDD core control techniques may be used to decrease a core voltage below the power supply voltage (VDD) used for the pass gate transistors. This reduces the required drive current of the PMOS pull up transistors to allow an NMOS pass gate to drive the inverter input below its trip point. However, these conventional techniques are problematic for various reasons, as is readily known to those of ordinary skill in the art.

### SUMMARY

In an embodiment of the invention, a memory device includes a memory array having a plurality of memory cells. At least two or more of the memory cells in the memory array include a first power supply node, a second power supply node, a first virtual power supply node, and a second virtual power supply node, a latch circuit and a write assist circuit. The latch circuit includes a first inverter and a second inverter connected in a cross-coupled inverter configuration. The first inverter is connected between the first virtual power supply node and the second power supply node, and the second inverter is connected between the second virtual power supply node and the second power supply node. The write assist circuit selectively supplies power to the first and second virtual power supply nodes of the memory cell during access operations of the memory cell. The write assist circuit is controlled by a first control signal to switchably connect and disconnect the first power supply node to and from the first and second virtual power supply nodes of the memory cell, and a second control signal to switchably connect and disconnect at least one of the first and second virtual power supply nodes of the memory cell to a virtual power supply node of an adjacent memory cell of an adjacent row in the memory array.

Other embodiments of the invention will become apparent.

### DESCRIPTION OF THE FIGURES

FIG. 1 is a schematic illustration of a semiconductor memory device.

FIG. 2 is a high-level block diagram of a memory array having write assist circuitry shared between adjacent memory cells of adjacent rows of the memory array, according to an embodiment of the invention.

FIG. 3 is a schematic circuit diagram of a memory cell having write assist circuitry that is shared between adjacent memory cells of adjacent rows of a memory array, according to an embodiment of the invention.

FIG. 4 is a schematic circuit diagram illustrating further details of the memory cell of FIG. 3 sharing write assist circuitry with adjacent memory cells of adjacent rows of a memory array, according to an embodiment of the invention.

FIG. 5 is a schematic circuit diagram of a memory cell having write assist circuitry that is shared between adjacent memory cells of adjacent rows of a memory array, according to another embodiment of the invention.

FIG. 6 is a schematic circuit diagram of a memory cell having write assist circuitry that is shared between adjacent memory cells of adjacent rows of a memory array, according to yet another embodiment of the invention.

FIG. 7 is a schematic circuit diagram of a memory cell having write assist circuitry that is shared between adjacent memory cells of adjacent rows of a memory array, according to another embodiment of the invention.

FIG. 8 is a schematic circuit diagram of a memory cell having write assist circuitry that is shared between adjacent memory cells of adjacent rows of a memory array, according to yet an embodiment of the invention.

FIG. 9 is a block diagram of a processing device that incorporates the memory device of FIG. 1.

FIG. 10 is a block diagram of a processor integrated circuit that incorporates the memory device of FIG. 1 as an embedded memory.

### WRITTEN DESCRIPTION

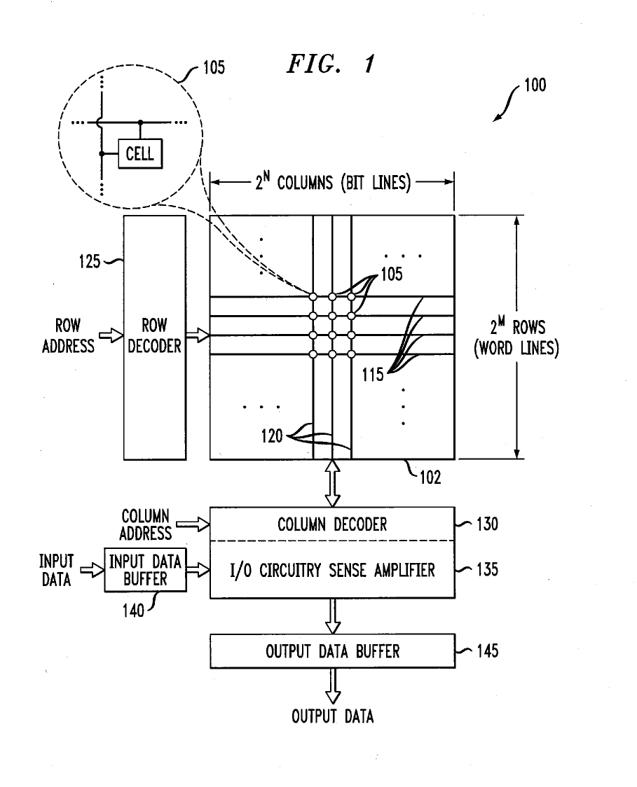

FIG. 1 is a schematic illustration of a semiconductor memory device 100. The memory device 100 comprises a memory array 102. The memory array 102 comprises a plurality of memory cells 105 each configured to store data. For example, the memory cells 105 may store a single bit of data, and such memory cells are also referred to herein as bit-cells. Each memory cell 105 is coupled to a corresponding row or wordline 115 and column or bitline 120, wherein a memory cell 105 is located at each point where a wordline intersects with a bitline. The memory cells 105 of the memory array 102 are illustratively arranged in 2^{N} columns and 2^{M} rows. The values selected for N and M in a given implementation will generally depend upon on the data storage requirements of the application in which the memory device is utilized.

One or more memory cells 105 of the memory array 102 can be activated for writing data thereto or reading data therefrom by application of appropriate row and column addresses to respective row decoder 125 and column decoder 130. Other elements of the memory device 100 include an input/output (I/O) gating and sense amplifier element 135, an input data buffer 140 and an output data buffer 145. Conventional embodiments and operations of the memory device elements such as row decoder 125, column decoder 130, gating and sense amplifier 135 and buffers 140, 145 are well understood in the art and will not be described in detail herein.

Although memory array 102 is identified in FIG. 1 as comprising the cells 105 and their associated wordlines and bit lines 115 and 120, the term “memory array” as used herein is intended to be more broadly construed, and may encompass one or more associated elements such as the row and column decoders 125 and 130, the gating and sense amplifier 135, or the input and output data buffers 140 and 145.

The memory device 100 of FIG. 1 may include other elements in addition to or in place of those specifically shown, including one or more elements of a type commonly found in a conventional implementation of such a memory device. These and other conventional elements, being well understood by those skilled in the art, are not described in detail herein. It should also be understood that the particular arrangement of elements shown in FIG. 1 is presented by way of illustrative example only. Those skilled in the art will recognize that a wide variety of other memory device configurations may be used to implement write assist circuitry according to embodiments of the invention.

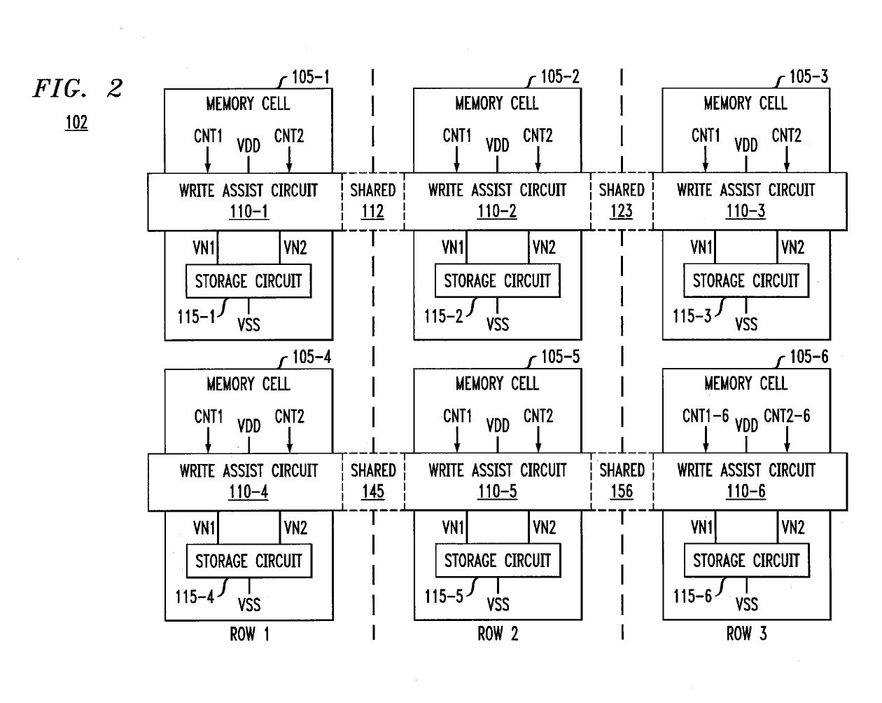

Embodiments of the memory device 100 as shown in FIG. 1 comprise a memory array of memory cells having shared write assist circuitry to enable ultra-low voltage operation and increased integration density. For example, FIG. 2 is a high-level block diagram of a memory array having write assist circuitry shared between adjacent memory cells of adjacent rows of the memory array, according to an embodiment of the invention. In general, FIG. 2 illustrates an embodiment of the memory array 102 of FIG. 1 comprising a plurality of memory cells (e.g., memory cells 105-1, 105-2, 105-3, 105-4, 105-5, and 105-6) in three rows of the memory array 102. In particular, the memory cells 105-1 and 105-4 are within a first row (ROW 1) of the memory array 102, the memory cells 105-2 and 105-5 are within a second row (ROW 2) of the memory array 102, and the memory cells 105-3 and 105-6 are within a third row (ROW 3) of the memory array 102.

In one embodiment as shown in FIG. 2, each memory cell 105-1, 105-2, 105-3, 105-4, 105-5, and 105-6 comprises a first power supply node VDD, a second power supply node VSS, a first virtual power supply node VN1, and a second virtual power supply node VN2, a respective write assist circuit 110-1, 110-2, 110-3, 110-4, 110-5, and 110-6, and a respective storage circuit 115-1, 115-2, 115-3, 115-4, 115-5, and 115-6. In one embodiment of the invention, each storage circuit 115-1, 115-2, 115-3, 115-4, 115-5, and 115-6 comprises a latch circuit for storing one bit of information, wherein the latch circuit comprises a first inverter and a second inverter connected in a cross-coupled inverter configuration, wherein the first inverter is connected between the first virtual power supply node and the second power supply node, and wherein the second inverter is connected between the second virtual power supply node and the second power supply node.

The write assist circuits 110-1, 110-2, 110-3, 110-4, 110-5, and 110-6, selectively supply power to the first and second virtual power supply nodes of a respective memory cell during access operations of the respective memory cell. Furthermore, portions of the write assist circuitry is shared between adjacent memory cells of adjacent rows to enable ultra-low voltage operation and increased integration density. For example, as generically illustrated in FIG. 2, the memory array 102 comprises a shared portion 112 of the write assist circuits 110-1 and 110-2 between adjacent memory cells 105-1 and 105-2 in adjacent rows (Rows 1 and 2), a shared portion 123 of the write assist circuits 110-2 and 110-3 between adjacent memory cells 105-2 and 105-3 in adjacent rows (Rows 2 and 3), a shared portion 145 of the write assist circuits 110-4 and 110-5 between adjacent memory cells 105-4 and 105-5 in adjacent rows (Rows 1 and 2), and a shared portion 156 of the write assist circuits 110-5 and 110-6 between adjacent memory cells 105-5 and 105-6 in adjacent rows (Rows 2 and 3).

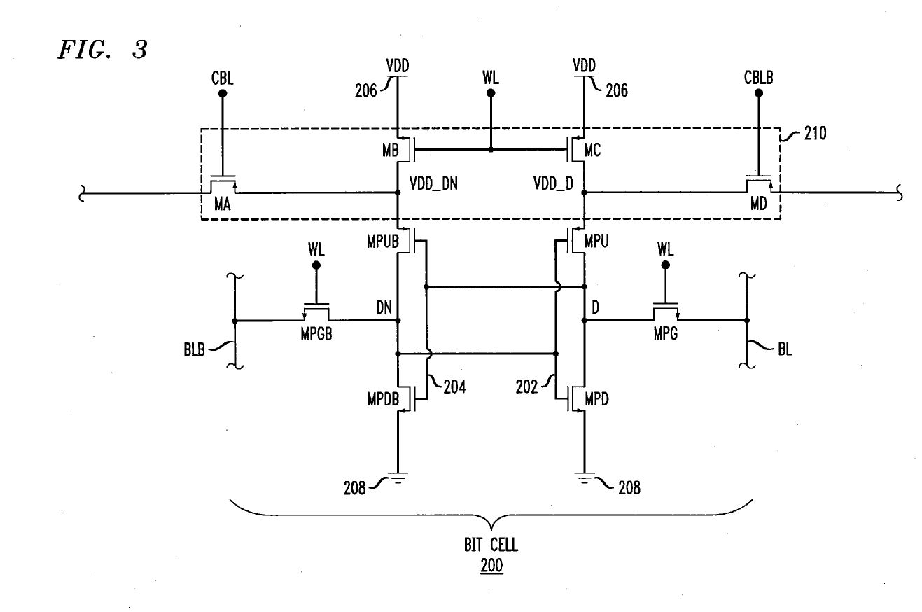

Each write assist circuit 110-1, 110-2, 110-3, 110-4, 110-5, and 110-6 is controlled by at least a first control signal CNT1 to switchably connect and disconnect the first power supply node VDD to and from the first and second virtual power supply nodes VN1 and VN2 of a respective memory cell 105-1, 105-2, 105-3, 105-4, 105-5, and 105-6. Moreover, each write assist circuit 110-1, 110-2, 110-3, 110-4, 110-5, and 110-6 is controlled by at least a second control signal CNT2 to switchably connect and disconnect at least one of the first and second virtual power supply nodes VN1, VN2 of a respective memory cell 105-1, 105-2, 105-3, 105-4, 105-5, and 105-6 to a virtual power supply node of an adjacent memory cell of an adjacent row in the memory array, to thereby provide a static power supply during certain memory operations using shared portions 112, 123, 145 and 156 of the write assist circuitry. Various alternate embodiments of the memory array 102 shown in FIG. 2 will now be discussed in further detail with reference to FIGS. 3-8.

FIG. 3 is a schematic circuit diagram of a memory cell having write assist circuitry that is shared between adjacent memory cells of adjacent rows of a memory array, according to an embodiment of the invention. In particular, FIG. 3 shows a memory cell 200 in the form of an SRAM bit-cell which comprises latch circuitry 202/204 that stores a data bit, and pass gate circuitry comprising a first NMOS transistor MPG (or first access transistor) and a second NMOS transistor MPGB (or second access transistor), which enables read and write access to the memory cell 200. The memory cell 200 further includes a first power supply node 206, a second power supply node 208, a first virtual power supply node VDD_D, a second virtual power supply node VDD_DN, a first internal data node D (or uncomplemented data node), and a second internal data node DN (or complemented data node). In one embodiment, the first power supply node 206 is connected to a first reference voltage VDD, for example. In one embodiment, the second power supply node 208 is connected to a second reference voltage, such as “ground” or a second reference voltage VSS, for example.

The latch circuitry 202/204 comprises a pair of cross-coupled inverters including a first inverter 202 and a second inverter 204, which are commonly referred to as a feed-forward inverter and a feed-back inverter, respectively, of the memory cell 200. The first inverter 202 comprises a PMOS pull-up transistor MPU and an NMOS pull-down transistor MPD, and the second inverter 202 comprises a PMOS pull-up transistor MPUB and an NMOS pull-down transistor MPDB. The first inverter 202 is connected between the first virtual power supply node VDD_D and the second power supply node 208. The second inverter 204 is connected between the second virtual power supply node VDD_DN and the second power supply node 208. More specifically, the source terminals of the PMOS pull-up transistors MPU and MPUB are connected to the virtual power supply nodes VDD_D and VDD_DN, respectively. In addition, drain terminals of the PMOS pull-up transistors MPU and MPUB are connected to the internal data nodes D and DN, respectively. Moreover, drain terminals of the NMOS pull-down transistors MPD and MPDB are connected to the internal data nodes D and DN, respectively, and source terminals of the NMOS pull-down transistors MPD and MPDB are coupled to the second power supply node 208 (e.g., ground potential). The cross-coupling of the first inverter 202 and the second inverter 204 is implemented by connecting gate terminals of the transistors MPU and MPD to the internal data node DN, and connecting gate terminals of the transistors MPUB and MPDB to the internal data node D.

A bit line connected to the memory cell 200 comprises a true bit line BL and a complementary bit line BLB (also referred to as data lines). The first access transistor MPG has a drain terminal coupled to the internal data node D, a source terminal connected to the true bit line BL, and a gate terminal coupled to a wordline WL. Similarly, the second access transistor MPGB has a drain terminal coupled to the internal data node DN, a source terminal connected to the complementary bit line BLB, and a gate terminal coupled to the wordline WL. A control signal applied to the wordline WL selectively connects the true bit line BL and complementary bit line BLB to the internal data nodes D and DN, respectively, through the respective first and second access transistors MPG and MPGB.

The memory cell 200 further comprises a write assist circuit 210 comprising PMOS transistors MA, MB, MC and MD. The PMOS transistors MB and MC have gate terminals that are commonly connected to the wordline WL. The PMOS transistors MB and MC operate as switches that switchably connect the first power supply node 206 to the virtual power supply nodes VDD_DN and VDD_D, respectively, in response to a control signal applied to the wordline WL. For example, when the wordline WL is deactivated (logic 0), the PMOS transistors MB and MC are activated (turned on), and a reference voltage VDD present on the first power supply node 206 is applied to the virtual power supply nodes VDD_D and VDD_DN. The PMOS transistors MB and MC are controlled by the word line WL to ensure that all unselected memory cells are adequately powered to avoid loss of data in unselected cells/rows. On the other hand, when the wordline WL is activated (logic 1), the PMOS transistors MB and MC are deactivated (turned off), and the virtual power supply nodes VDD_D and VDD_DN are decoupled from the first power supply node 206. The PMOS transistors MB and MC (and similarly functional transistors) may be referred to herein as a “virtual power supply transistors”.

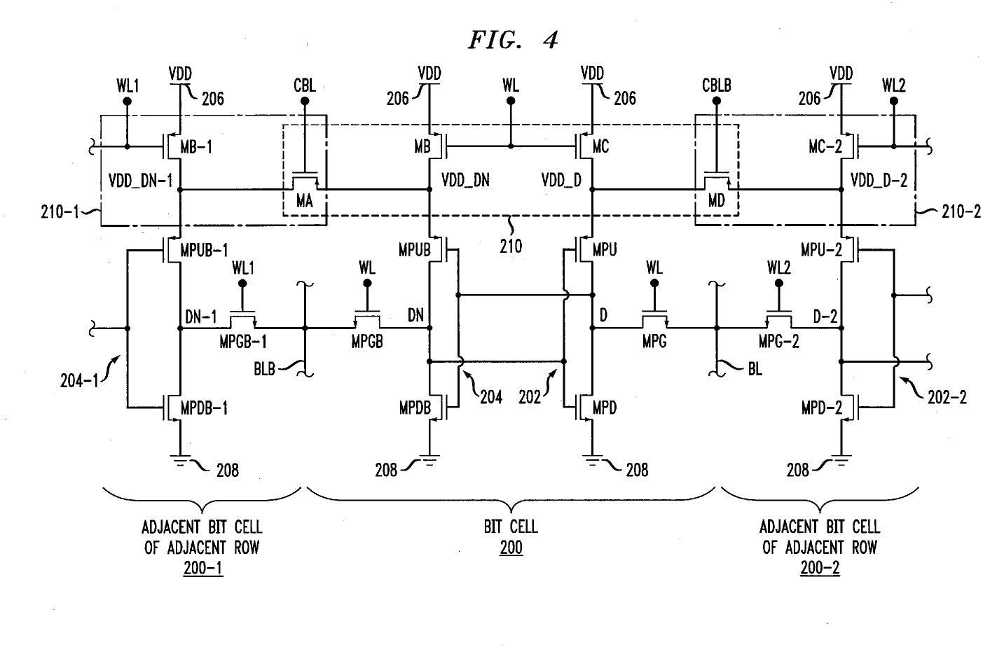

The PMOS transistors MA and MD have gate terminals connected to control lines that apply control signals CBL and CBLB to the gate terminals of the PMOS transistors MA and MD, respectively. In one embodiment of the invention, the control signals CBL and CBLB are generated by logically combining a plurality of control and/or data signals. As explained in further detail below with reference to FIG. 4, the PMOS transistors MA and MD operate as switches that switchably connect the virtual power supply nodes VDD_D and VDD_DN, respectively, of the memory cell 200, to virtual power supply nodes of adjacent memory cells in adjacent rows of a memory array. Moreover, the PMOS transistors MA and MD of the write assist circuit 210 are shared with write assist circuits of adjacent memory cells of adjacent rows in the memory array.

FIG. 4 is a schematic circuit diagram illustrating further details of the memory cell of FIG. 3 sharing write assist circuitry with adjacent memory cells of adjacent rows of a memory array, according to an embodiment of the invention. In particular, FIG. 4 illustrates the memory cell 200 of FIG. 3, as well as a portion of adjacent memory cells 200-1 and 200-2 from adjacent rows. A portion of the memory cell 200-1 shown in FIG. 4 includes a feed-back inverter 204-1 (formed of a PMOS pull-up transistor MPUB-1 and NMOS pull-down transistor MPDB-1), a passgate transistor MPGB-1, an internal data node DN-1, a virtual power supply node VDD_DN-1, and a portion of a write assist circuit 210-1 comprising a virtual power supply transistor MB-1 and the PMOS transistor MA, which is shared with the write assist circuit 210 of the adjacent memory cell 200. A wordline WL1 (for the adjacent row) is connected to gate terminals of the passgate transistor MPGB-1 and the virtual power supply transistor MB-1. Although a portion of the memory cell 200-1 is shown in FIG. 4, it is to be understood that the memory cells 200 and 200-1 are essentially mirror images of each other with respect to the commonly shared complementary bit line BLB and the PMOS transistor MA

Moreover, a portion of the memory cell 200-2 shown in FIG. 4 includes a feed-forward inverter 202-1 (formed of a PMOS pull-up transistor MPU-2 and NMOS pull-down transistor MPD-2), a passgate transistor MPG-2, an internal data node D-2, a virtual power supply node VDD_D-2, and a portion of a write assist circuit 210-2 comprising a virtual power supply transistor MC-2 and the PMOS transistor MD, which is shared with the write assist circuit 210 of the adjacent memory cell 200. A wordline WL2 (for the adjacent row) is connected to gate terminals of the passgate transistor MPG-2 and the virtual power supply transistor MC-2. Although a portion of the memory cell 200-2 is shown in FIG. 4, it is to be understood that the memory cells 200 and 200-2 are essentially mirror images of each other with respect to the commonly shared true bit line BL and the PMOS transistor MD.

In FIG. 4, the write assist circuits 210, 210-1 and 210-2 of respective memory cells 200, 200-1 and 200-2 are the same, except that the write assist circuits 210 and 210-1 share the PMOS transistor MA, and the write assist circuits 210 and 210-2 share the PMOS transistor MD. In this regard, the PMOS transistors MA and MD (and other functionally similar transistors) are alternatively referred to herein as “shared write assist transistors.” When a logic 0 signal is applied to the control signal line CBL, the PMOS transistor MA is turned on, thereby connecting the virtual power supply node VDD_DN of the memory cell 200 with the virtual power supply node VDD_DN-1 of the adjacent memory cell 200-1. Similarly, when a logic 0 signal is applied to the control signal line CBLB, the PMOS transistor MD is turned on, thereby connecting the virtual power supply node VDD_D of the memory cell 200 with the virtual power supply node VDD_D-2 of the adjacent memory cell 200-2.

The memory cell 200 shown in FIGS. 3 and 4, can perform a number of different memory access operations in conjunction with the write assist circuit 210, including, by way of example, a write operation without the use of a bit-write mask, a write operation with the use of a bit-write mask, and a read operation. When accessing the memory cell 200, the corresponding wordline WL is activated, which results in deactivating (turning off) the virtual power supply transistors MB and MC of the write assist circuit 210 of the memory cell 200. Depending on the memory access operation, however, either one or both of the shared write assist transistors MA and MD of the write assist circuit 210 will be activated (via control signals applied to the control signal lines CBL and CBLB) to provide a static power supply to one or both of the virtual supply nodes VDD_D N and VDD_D from the adjacent memory cells 200-1 and/or 200-2. Various modes of operation of the memory cell 200 will now be discussed in further detail with reference to FIG. 4.

In one embodiment, the memory cell 200 of FIG. 4 is configured to perform a write operation without use of the bit-write mask as follows. Prior to initiating a write operation, the bit lines BL and BLB are pre-charged to logic 1 (e.g., VDD) and the control signal lines CBL and CBLB, and wordline WL are set to logic 0 (e.g., VSS). Moreover, the wordlines WL1 and WL2 of the adjacent rows are set to logic 0. Thus, in this initial state, the passgate transistors MPG and MPGB of the memory cell 200 are deactivated (in a non-conducting or off state), the virtual power supply transistors MB and MC and shared write assist transistors MA and MD of the write assist circuit 210 are activated (in a conducting or on state), and the virtual power supply transistors (e.g., MB-1 and MC-2) of the respective write assist circuits 210-1 and 210-2 of the adjacent memory cells 200-1 and 200-2 are activated. This initial state ensures that the both virtual power supply nodes VDD_D and VDD_DN of the memory cell 200 will settle to VDD though a parallel combination of the PMOS transistors MA/MB and MC/MD.

Next, to perform a write operation of the memory cell 200, depending on the logic level of the data bit to be written to the memory cell 200, one of the shared write assist transistors MA and MD will remain activated, while the other is deactivated, so that power is cut off to the internal data node D or DN that needs to be forced to logic 0. More specifically, by way of example, assume that a data bit of logic 1 will be written to the memory cell 200. To commence a logic 1 write operation (without bit-write mask), the bit line BLB is discharged to VSS while the bit line BL is maintained at VDD. Moreover, the control signal line CBLB is maintained at VSS while the control signal line CBL transitions to VDD to deactivate the shared write assist transistor MA. After the bit BLB discharges to VSS, the wordline WL is set to VDD to activate the passgate transistors MPG and MPGB, and to deactivate the virtual power supply transistors MB and MC of the write assist circuit 210.

In this state, since the shared write assist transistor MD remains activated (while the virtual power supply transistor MC is deactivated), power is provided to the virtual power supply node VDD_D from the adjacent memory cell 200-2. In particular, the virtual power supply node VDD_D is connected to the virtual power supply node VDD_D-2 of the adjacent memory cell 200-2 through the shared write assist transistor MD, which in turn is connected to the first power supply node 206 through the virtual power supply transistor MC-2 of the write assist circuit 210-2 of the adjacent memory cell 200-2. As such, current flows from the first power supply node 206 through the transistors MC-2 and MD to supply power to the virtual power supply node VDD_D.

Moreover, in this state, since the transistors MA and MB are both deactivated, the virtual power supply node VDD_DN of the memory cell 200 is floating during the logic 1 write operation. Since the VDD_DN node remains floating during the write operation, the static drive current through the PMOS pull-up transistor MPUB is negligible regardless of local variations in the threshold voltage Vth of the PMOS pull-up transistor MPUB and passgate transistor MPGB. This negligible source current of the PMOS pull-up transistor MPUB ensures that the NMOS pass-gate transistor MPGB will be able to pull down the internal data node DN below a trip point of an inverter comprised of transistors MD/MPU/MPD, even with minimal drive current.

When the internal data node DN is driven below the trip point of the inverter comprised of transistors MD/MPU/MPD, the PMOS pull-up transistor MPU is activated and charges the internal data node D to VDD through the PMOS transistor stack comprising transistors MD and MC-2. Since the virtual power supply node VDD_D is set to VDD prior to initiating the write operation, the internal data node D will recover to VDD with in short time. Furthermore, since the virtual power supply node VDD_DN is floating (with small charge on a very small capacitance), the internal data node DN discharges to the trip point of the inverter comprised of transistors MD/MPU/MPD within a predictable duration by minimizing the charge-sharing between nodes DN and VDD_DN. Because of the predictability in the flip-time and recovery time of the memory cell 200, we can minimize the word-line pulse width and the duration between the flip time and deactivation of the wordline WL, which improves the write cycle time.

Similar operations apply when a data bit of logic 0 is written to the memory cell 200. In particular, to commence a logic 0 write operation (without bit-write mask), the bit line BL is discharged to VSS while the bit line BLB is maintained at VDD. Moreover, the control signal line CBL is maintained at VSS while the control signal line CBLB transitions to VDD to deactivate the shared write assist transistor MD. After the bit BLB discharges to VSS, the wordline WL is set to VDD to activate the passgate transistors MPG and MPGB, and to deactivate the virtual power supply transistors MB and MC of the write assist circuit 210.

In this state, since the shared write assist transistor MA remains activated (while the virtual power supply transistor MB is deactivated), power is provided to the virtual power supply node VDD_DN from the adjacent memory cell 200-1. In particular, the virtual power supply node VDD_DN is connected to the virtual power supply node VDD_DN-1 of the adjacent memory cell 200-1 through the shared write assist transistor MA, which in turn is connected to the first power supply node 206 through the virtual power supply transistor MB-1 of the write assist circuit 210-1 of the adjacent memory cell 200-1. As such, current flows from the first power supply node 206 through the transistors MB-1 and MA to supply power to the virtual power supply node VDD_DN.

Moreover, in this state, since the transistors MD and MC are both deactivated, the virtual power supply node VDD_D of the memory cell 200 is floating during the logic 0 write operation. Since the VDD_D node remains floating during the write operation, the static drive current through the PMOS pull-up transistor MPU is negligible regardless of local variations in the threshold voltage Vth of the PMOS pull-up transistor MPU and passgate transistor MPG. This negligible source current of the PMOS pull-up transistor MPU ensures that the NMOS pass-gate transistor MPG will be able to pull down the internal data node D below a trip point of an inverter comprised of transistors MA/MPUB/MPDB, even with minimal drive current.

When the internal data node D is driven below the trip point of the inverter comprised of transistors MA/MPUB/MPDB, the PMOS pull-up transistor MPUB is activated and charges the internal data node DN to VDD through the PMOS transistor stack comprising transistors MA and MB-1. Since the virtual power supply node VDD_DN is set to VDD prior to initiating the write operation, the internal data node DN will recover to VDD with in short time. Furthermore, since the virtual power supply node VDD_D is floating (with small charge on a very small capacitance), the internal data node D discharges to the trip point of the inverter comprised of transistors MA/MPUB/MPDB within a predictable duration by minimizing the charge-sharing between nodes D and VDD_D.

In another embodiment of the invention, the memory cell 200 of FIG. 4 is configured to perform a write operation using a bit-write mask, as follows. In this operation, the memory cell 200 is masked from a write operation to maintain the data stored in the memory cell 200. Prior to initiating a bit-write mask operation, the bit lines BL and BLB are pre-charged to VDD and the control signal lines CBL and CBLB, and wordline WL are set to VSS. Moreover, the wordlines WL1 and WL2 of the adjacent rows are set to VSS. Thus, in this initial state, the passgate transistors MPG and MPGB of the memory cell 200 are deactivated, the virtual power supply transistors MB and MC and shared write assist transistors MA and MD of the write assist circuit 210 are activated, and the virtual power supply transistors (e.g., MB-1 and MC-2) of the respective write assist circuits 210-1 and 210-2 of the adjacent memory cells 200-1 and 200-2 are activated.

Next, to perform a bit-write mask operation of the memory cell 200, the control signal lines CBL and CBLB are maintained at VSS, which causes the shared write assist transistors MA and MD to remain activated, thereby providing a static power supply to the virtual power supply nodes VDD_DN and VDD_D from the adjacent memory cells 200-1 and 200-2. Then, the precharge on the bit lines BL and BLB is released, and the wordline WL is activated (set to VDD) which deactivates the virtual power supply transistors MB and MC. Moreover, activation of the wordline WL causes one of the bit lines BL or BLB to discharge, resulting in a dummy read operation on the bit lines which masks the write operation and which does not disturb the data stored in the memory cell 200. The internal data nodes D and DN maintain the data previously stored in the memory cell 200.

In another embodiment of the invention, the memory cell 200 of FIG. 4 is configured to perform a read operation, as follows. Prior to initiating a read mask operation, the bit lines BL and BLB are pre-charged to VDD and the control signal lines CBL and CBLB, and wordline WL are set to VSS. Moreover, the wordlines WL1 and WL2 of the adjacent rows are set to VSS. Thus, in this initial state, the passgate transistors MPG and MPGB of the memory cell 200 are deactivated, the virtual power supply transistors MB and MC and shared write assist transistors MA and MD of the write assist circuit 210 are activated, and the virtual power supply transistors (e.g., MB-1 and MC-2) of the respective write assist circuits 210-1 and 210-2 of the adjacent memory cells 200-1 and 200-2 are activated.

Next, to perform a read operation of the memory cell 200, the control signal lines CBL and CBLB are maintained at VSS, which causes the shared write assist transistors MA and MD to remain activated, thereby providing a static power supply to the virtual power supply nodes VDD_DN and VDD_D from the adjacent memory cells 200-1 and 200-2. Then, the precharge on the bit lines BL and BLB is released, and the wordline WL is activated (set to VDD) which deactivates the virtual power supply transistors MB and MC. Moreover, activation of the wordline WL causes one of the bit lines BL or BLB to discharge, while the other bit line is retained at VDD. The voltage level of the discharged bit line read out through a sense inverter, using known techniques. In the embodiment of FIG. 4, since the bit lines BL and BLB are only connected to the passgate transistors MPG and MPGB, respectively, the capacitance on the bit lines BL and BLB is minimized resulting in faster discharge rates and, thus, improving the read access time.

In the embodiment of FIG. 4, the control signals that are applied on the control signal lines CBL and CBLB are generated using a combinatorial logic circuit that logically combines a plurality of memory access and/or data signals. For example, in one embodiment of the invention, the CBL and CBLB control signal are generated as logical combination of a Readwrite (RD/WZ) signal, a Write Enable signal, and a data input signal. More specifically, in one embodiment, the following Table 1 illustrates the logic levels of the encoded control signals CBL and CBLB that are generated for different memory access operations based on various control and data signals:

TABLE 1

| | Write | | | | | | Memory |
|---|---|---|---|---|---|---|---|
| RD/WZ | Enable | Data | CBL | CBLB | BL | BLB | Operation |
| 1 | X | x | 0 | 0 | 1 | 1 | Read |
| 0 | 0 | x | 0 | 0 | 1 | 1 | Mask Write |
| 0 | 1 | 0 | 0 | 1 | 0 | 1 | Write 0 |
| 0 | 1 | 1 | 1 | 0 | 1 | 0 | Write 1 |

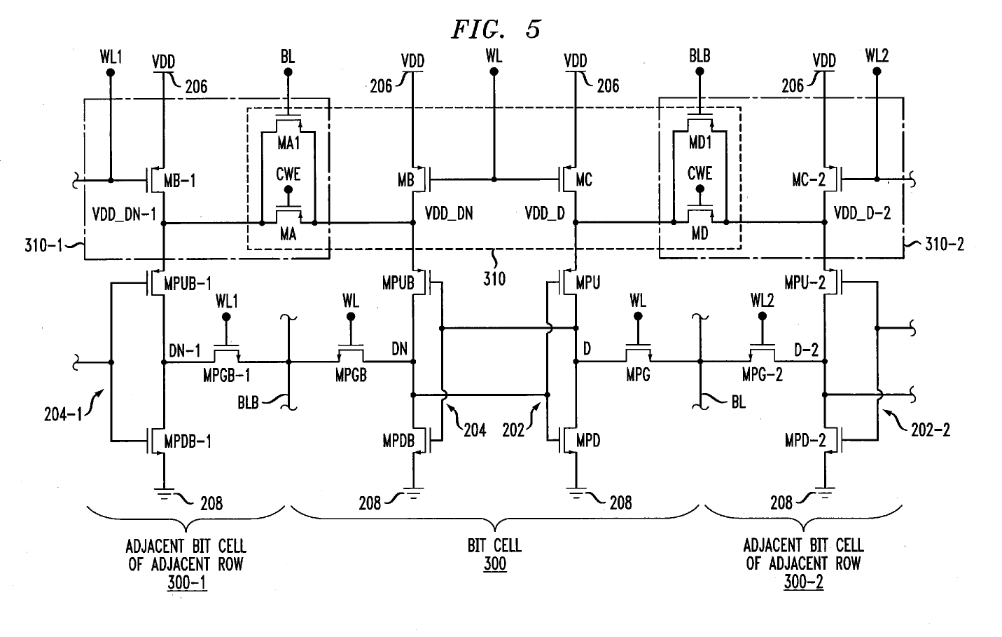

FIG. 5 is a schematic circuit diagram of a memory cell having write assist circuitry that is shared between adjacent memory cells of adjacent rows of a memory array, according to another embodiment of the invention. In particular, FIG. 5 shows a memory cell 300 having a write assist circuit 310, as well as portions of adjacent memory cells 300-1 and 300-2 and respective write assist circuits 310-1 and 310-2 from adjacent rows. The memory cells 300, 300-1 and 300-2 are similar in circuit architecture to the respective memory cells 200, 200-1 and 200-2 as shown in FIG. 4, except that the write assist circuits 310, 310-1 and 310-2 shown in FIG. 5 include additional shared write assist transistors MA1 and MD1.

More specifically, as shown in FIG. 5, a shared portion of the write assist circuits 310 and 310-1 comprises two shared write assist transistors MA and MA1, which are connected in parallel. Moreover, a shared portion of the write assist circuits 310 and 310-2 comprises two shared write assist transistors MD and MD1, which are connected in parallel. A CWE (column write enable) control line is commonly connected to gate terminals of the shared write assist transistors MA and MD. The true bit line BL is connected to a gate terminal of the shared write assist transistor MA1, and the complementary bit line BLB is connected to a gate terminal of the shared write assist transistor MD1. Although a portion of the memory cells 300-1 and 300-2 are shown in FIG. 5, it is to be understood that the memory cells 300 and 300-1 are essentially mirror images of each other with respect to the commonly shared complementary bit line BLB and the parallel-connected shared write assist transistors MA and MA1, and that the memory cells 300 and 300-2 are essentially mirror images of each other with respect to the commonly shared true bit line BL and the parallel-connected shared write assist transistors MD and MD1.

The embodiment of FIG. 5 operates similar to the embodiment discussed above with reference to FIG. 4, except that the embodiment of FIG. 5 eliminates the need for additional combinatorial logic in the input/output periphery to generate control signals for the CBL and CBLB control lines. Moreover, the embodiment reduces a number of metal wiring (track) needed to route the control lines CBL and CBLB, since only the one CWE control line track is needed. In one embodiment of the invention, the following Table 2 illustrates the logic levels of control signals CWE, BL and BLB that are generated for different memory access operations based on the various control and the logic level of the data signals to be written:

TABLE 2

| | | | | Memory |
|---|---|---|---|---|
| CWE | Data | BL | BLB | Operation |
| 0 | X | 1 | 1 | Read |
| 0 | X | 1 | 1 | Mask Write |
| 1 | 0 | 0 | 1 | Write 0 |
| 1 | 1 | 1 | 0 | Write 1 |

As shown in the above Table 2, during a read operation or a mask write operation of the memory cell 300 of FIG. 5, the control signal line CWE is set to logic 0, which activates the shared write assist transistors MA and MD. As such, a static power supply is provided to the virtual power supply nodes VDD_DN and VDD_D from the adjacent memory cells 300-1 and 300-2 irrespective of the logic levels of BL and BLB applied to the gate terminals of MA1 and MD1, respectively. During a write operation, the control signal line CWE is set to logic 1, which deactivates both shared write assist transistors MA and MD. Furthermore, depending on the logic levels of the control signals applied to the bit lines BL and BLB (more specifically, depending if a 0 or 1 is to be written to the memory cell 300), only one of the shared write assist transistors MA1 or MD1 will be activated so that static power is supplied to one of the virtual supply nodes VDD_DN or VDD_D from the adjacent memory cells 300-1 or 300-2.

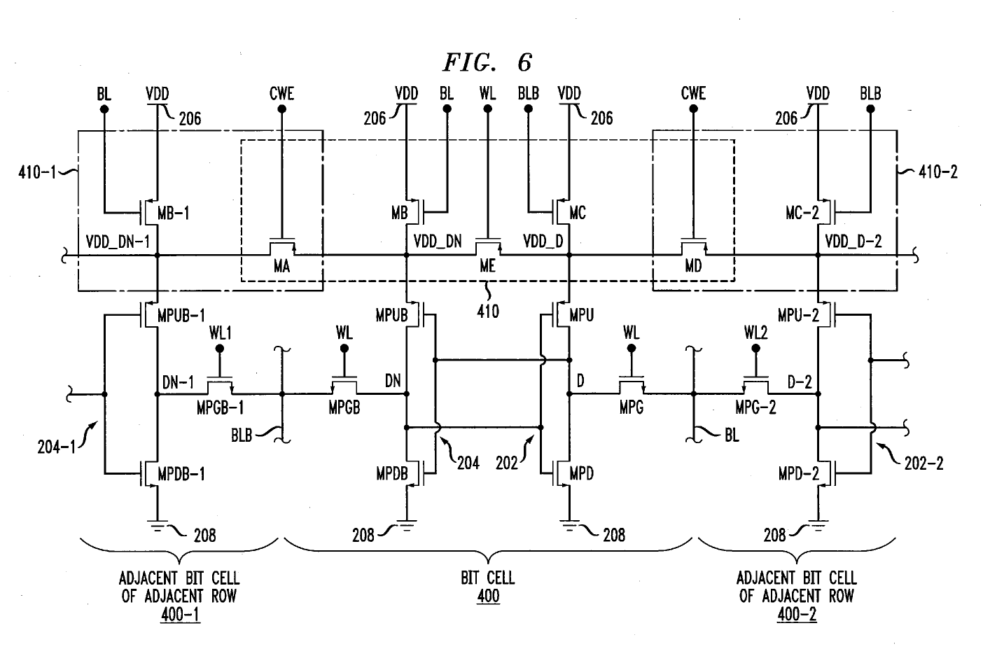

FIG. 6 is a schematic circuit diagram of a memory cell having write assist circuitry that is shared between adjacent memory cells of adjacent rows of a memory array, according to another embodiment of the invention. In particular, FIG. 6 shows a memory cell 400 having a write assist circuit 410, as well as portions of adjacent memory cells 400-1 and 400-2 and respective write assist circuits 410-1 and 410-2 from adjacent rows of a memory array. The memory cells 400, 400-1 and 400-2 are similar in circuit architecture to the respective memory cells 200, 200-1 and 200-2 as shown in FIG. 4, except that the write assist circuits 410, 410-1 and 410-2 shown in FIG. 6 include equalization transistors, and the virtual power supply transistors are switchably controlled by the bit lines BL and BLB.

More specifically, as shown in FIG. 6, the write assist circuit 410 comprises an equalization transistor ME connected between the virtual power supply nodes VDD_D and VDD_DN of the memory cell 400 In one embodiment, the equalization transistor ME is a PMOS transistor that has a gate terminal connected to the wordline WL. Although not specifically shown in FIG. 6, it is to be understood that the other write assist circuits 410-1 and 410-2 each have an equalization transistor connected between the virtual power supply nodes of the associated memory cell 400-1 and 400-2, with a gate terminal connected to a corresponding wordline for the corresponding row. Moreover, although a portion of the memory cells 400-1 and 400-2 are shown in FIG. 6, it is to be understood that the memory cells 400 and 400-1 are essentially mirror images of each other with respect to the commonly shared complementary bit line BLB and the shared write assist transistor MA, and that the memory cells 400 and 400-2 are essentially mirror images of each other with respect to the commonly shared true bit line BL and the shared write assist transistor MD.

As further shown in FIG. 6, a CWE control line is commonly connected to gate terminals of the shared write assist transistors MA and MD. The true bit line BL is connected to a gate terminal of the virtual power supply transistor MB that is connected to the virtual power supply node VDD_DN of the memory cell 400, as well as the corresponding virtual power supply transistors of other cells, e.g., the virtual power supply transistor MB-1 connected to the virtual power supply node VDD_DN-1 of the adjacent memory cell 400-1, etc. Moreover, the complementary bit line BLB is connected to a gate terminal of the virtual power supply transistor MC that is connected to the virtual power supply node VDD_D of the memory cell 400, as well as the corresponding virtual power supply transistors of other cells, e.g., the virtual power supply transistor MC-2 connected to the virtual power supply node VDD_D-2 of the adjacent memory cell 400-2, etc.

In the embodiment of FIG. 6, the wordlines are used to equalize the virtual power supply nodes of unselected rows. In particular, for the memory cell 400 shown in FIG. 6, when the wordline WL is set at logic 0, the equalization transistor ME is active and connects (shorts) the virtual power supply nodes VDD_D and VDD_DN together. When a memory operation is commenced on the memory cell 400, the wordline WL is set to logic 1 and the equalization transistor ME is deactivated (while the equalization transistors (not shown) of the adjacent memory cells 400-1 and 400-2 remain activated as wordlines WL1 and WL2 remain deactivated at logic 0).

In one embodiment of the invention, Table 2 illustrates the logic levels of control signals CWE, BL and BLB that are generated for different memory access operations of the embodiment of FIG. 6, based on the various control and the data signals. As shown in Table 2, during a read operation or a mask write operation of the memory cell 400 of FIG. 6, the control signal line CWE is set to logic 0, which activates the shared write assist transistors MA and MD. As such, a static power supply is provided to the virtual power supply nodes VDD_DN and VDD_D from the adjacent memory cells 400-1 and 400-2 irrespective of the logic levels of BL and BLB.

On the other hand, during a write operation, the control signal line CWE is set to logic 1, which deactivates both shared write assist transistors MA and MD. Depending on the logic levels of the control signals applied to the bit lines BL and BLB (more specifically, depending if a 0 or 1 is to be written to the memory cell 400), only one of the virtual power supply transistors MB or MC will be activated, so that static power is supplied to one of the virtual supply nodes VDD_DN or VDD_D via the activated transistor MB or MC, respectively. In this embodiment, deactivation of the shared write assist transistors MA and MD during a write operation via the CWE control signal eliminates a risk of transient coupling of the data signal to an adjacent memory cell during the write operation.

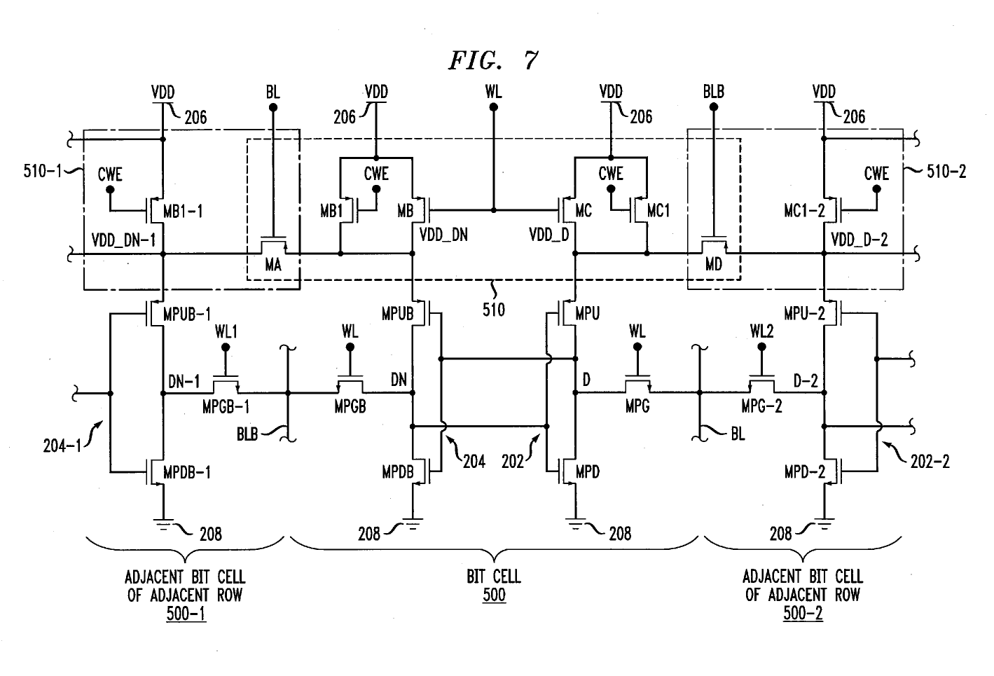

FIG. 7 is a schematic circuit diagram of a memory cell having write assist circuitry that is shared between adjacent memory cells of adjacent rows of a memory array, according to another embodiment of the invention. In particular, FIG. 7 shows a memory cell 500 having a write assist circuit 510, as well as portions of adjacent memory cells 500-1 and 500-2 and respective write assist circuits 510-1 and 510-2 from adjacent rows. The memory cells 500, 500-1 and 500-2 are similar in circuit architecture to the respective memory cells 200, 200-1 and 200-2 as shown in FIG. 4, except that the write assist circuits 510, 510-1 and 510-2 shown in FIG. 7 include additional virtual power supply transistors MB1, MC1, MB1-1 and MC1-2 that are switchably controlled by the CWE control line. Moreover, the shared write assist transistors MA and MD are switchably controlled by the bit lines BL and BLB.

More specifically, as shown in FIG. 7, the write assist circuit 510 comprises additional virtual power supply transistors MB1 and MC1 that are connected in parallel with respective virtual power supply transistors MB and MC. While the virtual power supply transistors MB and MC are controlled by the wordline WL (as in the embodiment of FIG. 4), the corresponding parallel-connected virtual power supply transistors MB1 and MC1 are controlled by the CWE control line. It is to be understood that the other write assist circuits 510-1 and 510-2 have virtual power supply transistors (not specifically shown) connected in parallel with respective virtual power supply transistors MB1-1 and MC1-2, with gate terminal connected to the corresponding wordlines WL1 and WL2 for the adjacent rows. In this regard, although a portion of the memory cells 500-1 and 500-2 are shown in FIG. 7, it is to be understood that the memory cells 500 and 500-1 are essentially mirror images of each other with respect to the commonly shared complementary bit line BLB and the shared write assist transistor MA, and that the memory cells 500 and 500-2 are essentially mirror images of each other with respect to the commonly shared true bit line BL and the shared write assist transistor MD.

The embodiment of FIG. 7 provides an alternate embodiment in which the CWE and WL control lines operate in parallel, wherein the no additional combinatorial logic is needed for generating the CBL and CBLB signals (of FIG. 4). Moreover, in the embodiment of FIG. 7, current is shared between adjacent memory cells during a write operation, but not a read operation, thereby preventing possible corruption of the data during a read operation. For example, when a memory operation is commenced on the memory cell 500 in FIG. 7, the wordline WL is set to logic 1 and the virtual power supply transistors MB and MC are deactivated.

In one embodiment of the invention, Table 2 illustrates the logic levels of control signals CWE, BL and BLB that are generated for different memory access operations of the embodiment of FIG. 7, based on the various control and the data signals. As shown in Table 2 above, during a read operation or a mask write operation of the memory cell 500 of FIG. 7, the control signal line CWE is set to logic 0, which activates the virtual power supply transistors MB1 and MC1. Since the bit lines BL and BLB and wordline WL are all set at logic 1, the shared write assist transistors MA and MD and virtual power supply transistors MB and MC are deactivated. As such, a static power supply is provided to the virtual power supply nodes VDD_DN and VDD_D via the virtual power supply transistors MB1 and MC1, respectively.

During a write operation, the control signal line CWE is set to logic 1, which deactivates the virtual power supply transistors MB1 and MC1. Furthermore, since WL is set at logic 1, the virtual power supply transistors MB and MC are also deactivated. Furthermore, depending on the logic levels of the control signals applied to the bit lines BL and BLB (more specifically, depending if a 0 or 1 is to be written to the memory cell 500), only one of the shared write assist transistors MA or MD will be activated, so that static power is supplied to one of the virtual supply nodes VDD_D N and VDD_D from one of the adjacent memory cells 500-1 or 500-2, while the other one of the virtual supply nodes VDD_D N and VDD_D remains floating.

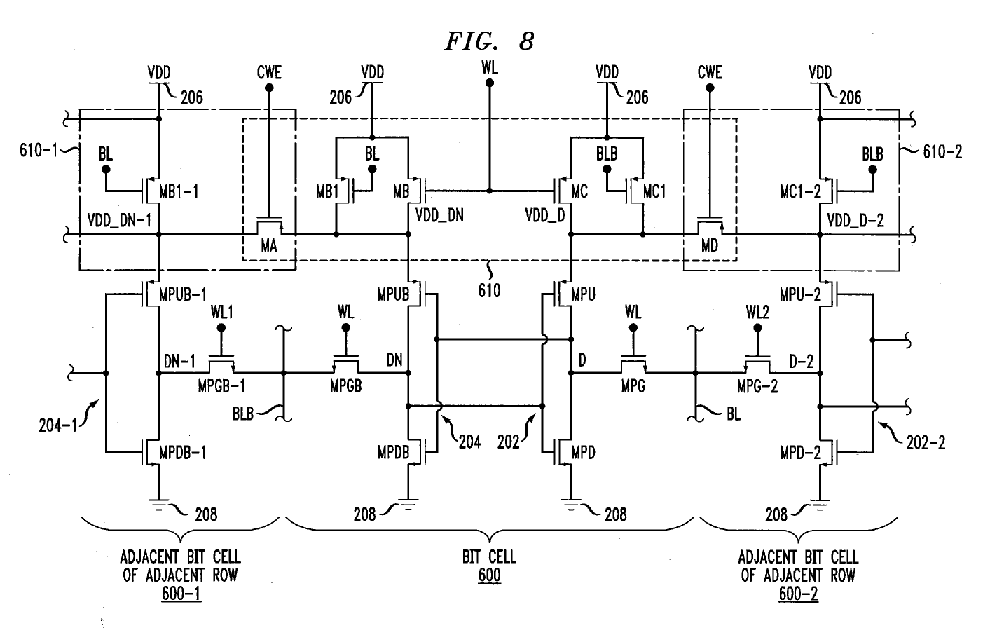

FIG. 8 is a schematic circuit diagram of a memory cell having write assist circuitry that is shared between adjacent memory cells of adjacent rows of a memory array, according to another embodiment of the invention. In particular, FIG. 8 shows a memory cell 600 having a write assist circuit 610, as well as portions of adjacent memory cells 600-1 and 600-2 from adjacent rows and respective write assist circuits 610-1 and 610-2. The embodiment of FIG. 8 is the same as the embodiment of FIG. 7, except that as shown in FIG. 8, the virtual power supply transistors MB1 and MB1-1 are switchably controlled by the true bit line BL, the virtual power supply transistors MC1 and MC1-2 are switchably controlled by the complementary bit line BLB, and the shared write assist transistors MA and MD are switchably controlled by the CWE control signal line.

The embodiment of FIG. 8 provides an alternate embodiment in which the CWE and WL control lines operate in parallel, wherein no additional combinatorial logic is needed for generating the CBL and CBLB signals (of FIG. 4). Moreover, in the embodiment of FIG. 8, current is shared between adjacent memory cells during a read operation, but not a write operation, thereby eliminating any risk of transient coupling of the signal to an adjacent cell during a write operation. For example, when a memory operation is commenced on the memory cell 600 in FIG. 8, the wordline WL is set to logic 1 and the virtual power supply transistors MB and MC are deactivated, while the corresponding virtual power supply transistors (not shown) in the write assist circuits 610-1 and 610-2 remain activated as WL1 and WL2 are set to logic 0.

As shown in Table 2 above, during a read operation or a mask write operation of the memory cell 600 of FIG. 8, the control signal line CWE is set to logic 0, which activates the shared write assist transistors MA and MD. Since the bit lines BL and BLB and wordline WL are set at logic 1, the virtual power supply transistors MB1, MB, MC, and MC1 are all deactivated. As such, a static power supply is provided to the virtual power supply nodes VDD_DN and VDD_D of the memory cell 600 from the adjacent memory cells 600-1 and 600-2 via the shared write assist transistors MA and MD. In this state, the virtual power supply nodes VDD_DN-1 and VDD_D-2 of the adjacent memory cells 600-1 and 600-2, respectively, are connected to the power supply node 206 through the virtual power supply transistors (not shown) of the write assist circuits 610-1 and 610-2, which remain activated by the logic 0 level applied to wordlines WL and WL in the adjacent rows.

During a write operation, the control signal line CWE is set to logic 1, which deactivates the shared write assist transistors MA and MD. Furthermore, since WL is set at logic 1, the virtual power supply transistors MB and MC are also deactivated. Furthermore, depending on the logic levels of the control signals applied to the bit lines BL and BLB (more specifically, depending if a 0 or 1 is to be written to the memory cell 600), only one of the virtual power supply transistors MB1 or MC1 will be activated, so that static power is supplied to one of the virtual supply nodes VDD_D N and VDD_D from a respective one of the virtual power supply transistors MB1 and MC1, while the other one of the virtual supply nodes VDD_D N and VDD_D remains floating for the write operation.

Various embodiments of a memory cell array with shared write assist circuitry as described above with reference to FIGS. 2, 3, 4, 5, 6, 7, and 8 provide advantages relative to conventional arrangements. For example, as indicated above, an SRAM array architecture with shared write assist circuitry between adjacent memory cells of adjacent rows provides a low voltage write capability, without the use of negative bootstrapping or charge pumps techniques. Indeed, by selectively disconnecting a power source from one of the virtual power supply nodes VDD_D or VDD_DN during a write operation, one of the internal data nodes D or DN of the memory cell can be readily pulled down when the memory cell array is operating at low voltages, even under worst case local variations in threshold voltages which cause a decrease in the overdrive of an NMOS pass gate transistor and increase in the overdrive of the PMOS pull-up transistor at lower operating voltages. Furthermore, by selectively disconnecting the virtual power supply nodes VDD_D and VDD_DN of the memory cells on a cell-by-cell basis, the write-ability of the memory cells can be improved without compromising the stability of other memory cells in a shared row or column of the memory array.

In addition, embodiments of shared write assist circuits as described above provide improved core-cell flip margin and write cycle time by enabling a reduction in the wordline pulse width. Moreover, the low-voltage write assist capabilities provided by the embodiments described herein results in an improved bit-cell yield. Moreover, shared write assist circuits according to embodiments of the invention provide improved read access times by reducing unwanted capacitance on the bit lines BL and BLB.

Further, by sharing resources/components between write assist circuits of adjacent memory cells, increased integration density of a memory array can be realized. Indeed. by sharing write assist transistors between adjacent memory cells, for example, a reduction in a number of transistors for the write assist circuits can be realized, while providing robust static write assist at lower operating voltages. Furthermore, in the embodiment of FIGS. 3 and 4, for example, a logical write assist control scheme with encoded control signals CBL and CBLB is achieved without relying on dynamic charge sharing and capacitors.

It should be noted that while memory devices according to embodiments of the invention are specifically discussed in the context of an SRAM device, write assist circuits and methods as discussed herein with reference to FIGS. 2, 3, 4, 5, 6, 7 and 8 can be adapted for use in other types of memory devices, including, for example, dynamic random access memory (DRAM), electrically erasable programmable ROM (EEPROM), magnetic RAM (MRAM), ferroelectric RAM (FRAM), phase-change RAM (PC-RAM), etc. In addition, other types of memory cell configurations may be used. For example, the memory cells 105 in the memory array 102 could be multi-level cells each configured to store more than one bit of data. Embodiments of the invention are thus, not limited in terms of the particular storage or access mechanism utilized in the memory device. Moreover, memory cell arrays with shared write assist circuitry can be implemented in a wide variety of different memory applications in which increased write speed is desirable such as in content addressable memories (CAMs) applications, which require write and compare operations to be performed within the same cycle. In other embodiments, a memory cell with shared write assist circuitry can be implemented in a register file, such as a register file having a single write port and multiple read ports.

It should be noted that use of PMOS transistors and NMOS transistors in the embodiments described above is by way of illustrative example. In other embodiments, the conductivity types of certain ones of the various transistors may be reversed, as would be appreciated by one skilled in the art. As a more particular example, the PMOS transistors of the write assist circuitry may be replaced with NMOS transistors and the NMOS pass gate transistors may be replaced with PMOS pass gate transistors, in conjunction with other straightforward modifications of the circuitry arrangements.

A memory device with shared write assist circuitry according to embodiments of the invention may be implemented as a stand-alone memory device, for example, as a packaged integrated circuit memory device suitable for incorporation into a higher-level circuit board or other system. Other types of implementations are possible, such as an embedded memory device, where the memory may be, for example, embedded into a processor or other type of integrated circuit device which comprises additional circuitry coupled to the memory device. More particularly, a memory device as described herein may comprise an embedded memory implemented within a microprocessor, digital signal processor (DSP), application-specific integrated circuit (ASIC), field-programmable gate array (FPGA) or other type of processor or integrated circuit device.

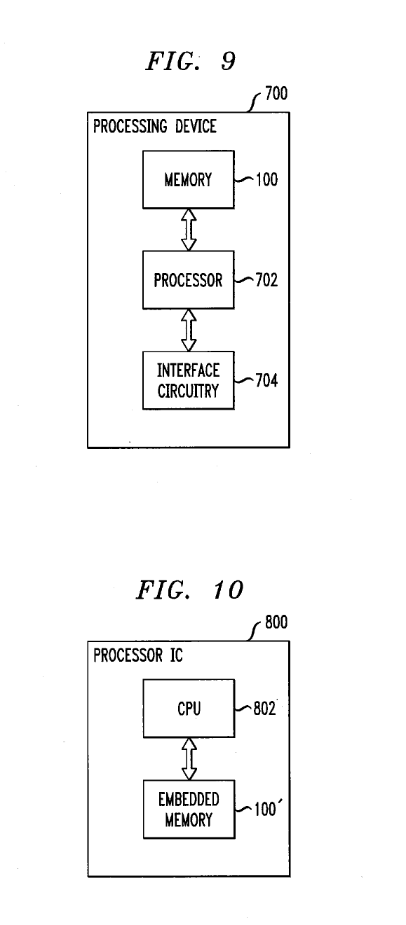

FIG. 9 shows an example of a processing device 700 which incorporates the memory device 100 of FIG. 1. In this embodiment, the memory device 100 is coupled to a processor 702. The processing device further includes interface circuitry 704 coupled to the processor 702. The processing device 700 may comprise, for example, a computer, a server or a portable communication device such as a mobile telephone. The interface circuitry 704 may comprise one or more transceivers for allowing the device 600 to communicate over a network.

Alternatively, processing device 700 may comprise a microprocessor, DSP or ASIC, with processor 702 corresponding to a central processing unit (CPU) and memory device 100 providing at least a portion of an embedded memory of the microprocessor, DSP or ASIC. FIG. 10 shows an example of an arrangement of this type, with processor integrated circuit 800 incorporating the memory device of FIG. 1 as an embedded memory 100′. The embedded memory 100′ in this embodiment is coupled to a CPU 802.

In an integrated circuit implementation of the invention, multiple integrated circuit dies are typically formed in a repeated pattern on a surface of a wafer. Each such die may include a device as described herein, and may include other structures or circuits. The dies are cut or diced from the wafer, then packaged as integrated circuits. One skilled in the art would know how to dice wafers and package dies to produce packaged integrated circuits. Integrated circuits so manufactured are considered part of this invention.

Although embodiments of the invention have been described herein with reference to the accompanying drawings, it is to be understood that embodiments of the invention are not limited to the described embodiments, and that various changes and modifications may be made by one skilled in the art resulting in other embodiments of the invention within the scope of the following claims.

What is claimed is:

1. A memory device comprising:
a memory array comprising a plurality of memory cells, wherein at least two or more memory cells each comprise:
a first power supply node, a second power supply node, a first virtual power supply node, and a second virtual power supply node;
a latch circuit comprising a first inverter and a second inverter, which are connected in a cross-coupled inverter configuration, wherein the first inverter is connected between the first virtual power supply node and the second power supply node, and wherein the second inverter is connected between the second virtual power supply node and the second power supply node; and
a write assist circuit to selectively supply power to the first and second virtual power supply nodes of the memory cell during access operations of the memory cell,
wherein the write assist circuit is controlled by a first control signal to switchably connect and disconnect the first power supply node to and from the first and second virtual power supply nodes of the memory cell, and
wherein the write assist circuit is controlled by a second control signal to switchably connect and disconnect at least one of the first and second virtual power supply nodes of the memory cell to a virtual power supply node of an adjacent memory cell of an adjacent row in the memory array.

2. The memory device of claim 1, wherein the first control signal is a wordline control signal.

3. The memory device of claim 1, wherein the second control signal is logically generated by a combination of a read/write control signal, a write enable signal, and a data signal.

4. The memory device of claim 1, wherein the second control signal is a data signal on a bit line.

5. The memory device of claim 1, wherein the second control signal is a column write enable control signal.

6. The memory device of claim 1, wherein the write assist circuit is controlled by a third control signal, in parallel with the first control signal, to switchably connect and disconnect the first power supply node to and from the first and second virtual power supply nodes of the memory cell based on logic levels of the first and third control signals.

7. The memory device of claim 1, wherein the write assist circuit is controlled by a fourth control signal, in parallel with the second control signal, to switchably connect and disconnect said at least one of the first and second virtual power supply nodes of the memory cell to the virtual power supply node of the adjacent memory cell of the adjacent row in the memory array.

8. An integrated circuit comprising the memory device of claim 1.

9. A processing device comprising the memory device of claim 1.

10. A memory device comprising:
a memory array comprising a plurality of memory cells, wherein at least two or more memory cells each comprise:
a first power supply node, a second power supply node, a first virtual power supply node, and a second virtual power supply node;
a latch circuit comprising a first inverter and a second inverter, which are connected in a cross-coupled inverter configuration, wherein the first inverter is connected between the first virtual power supply node and the second power supply node, and wherein the second inverter is connected between the second virtual power supply node and the second power supply node; and
a write assist circuit to selectively supply power to the first and second virtual power supply nodes of the memory cell during access operations of the memory cell, wherein the write assist circuit comprises:
a first switch coupled between the first power supply node and the first virtual power supply node of the memory cell;
a second switch coupled between the first power supply node and the second virtual power supply node of the memory cell; and
a third switch coupled between one of the first and second virtual power supply nodes of the memory cell and a virtual power supply node of an adjacent memory cell of an adjacent row in the memory array.

11. The memory device of claim 10, wherein the third switch is shared between the write assist circuit of the memory cell and a write assist circuit of said adjacent memory cell of said adjacent row in said memory array.

12. The memory device of claim 10, wherein the first and second switches of the write assist circuit are controlled by a first control signal to switchably connect and disconnect the first power supply node to and from the first and second virtual power supply nodes of the memory cell, and wherein the third switch of the write assist circuit is controlled by a second control signal to switchably connect and disconnect one of the first and second virtual power supply nodes of the memory cell to and from said virtual power supply node of said adjacent memory cell of said adjacent row in said memory array.

13. The memory device of claim 12, wherein the write assist circuit further comprises:
a fourth switch connected in parallel to the first switch;
a fifth switch connected in parallel to the second switch,
wherein the fourth switch and the fifth switch are controlled by a third control signal, in parallel with the first control signal, to switchably connect and disconnect the first power supply node to and from the first and second virtual power supply nodes of the memory cell based on logic levels of the first and third control signals.

14. The memory device of claim 13, wherein the third control signal comprises a same signal applied to the fourth and fifth switches.

15. The memory device of claim 13, wherein the third control signal comprises complementary signals of opposite polarity applied to the fourth and fifth switches.

16. The memory device of claim 12, wherein the write assist circuit further comprises a sixth switch connected to parallel with the third switch, wherein the sixth switch is controlled by a fourth control signal, in parallel with the second control signal, to switchably connect and disconnect said one of the first and second virtual power supply nodes of the memory cell to and from said virtual power supply node of said adjacent memory cell of said adjacent row in said memory array.

17. The memory device of claim 16, wherein the sixth switch is shared between the write assist circuit of the memory cell and a write assist circuit of said adjacent memory cell of said adjacent row in said memory array.

18. The memory device of claim 10, further comprising a seventh switch connected between the first and second virtual power supply nodes of the memory cell, wherein the seventh switch is controlled by a fifth control signal to equalize voltage of the first and second virtual power supply nodes.

19. The memory device of claim 19, wherein firth control signal is a wordline control signal, and wherein the first control signal comprises complementary bit line signals applied to the first and second switches.

20. An integrated circuit comprising the memory device of claim 10.

21. A processing device comprising the memory device of claim 10.

22. A method for accessing a memory cell in an array of memory cells, comprising:
maintaining a connection between a power supply node and a virtual power supply node of a given memory cell during a period of time in which the given memory cell is not accessed;
applying an access control signal to the given memory cell;
disconnecting the virtual power supply node of the given memory cell from the power supply node in response to the access control signal;
switchably connecting the virtual power supply node of the given memory cell to a virtual power supply node of an adjacent memory cell of an adjacent row in the memory array; and
using power applied from said virtual power supply node of said adjacent memory cell of said adjacent row in the memory array to access the given memory cell.
